(19) United States
(12) Patent Application Publication
(10) Pub. No.: US 2016/0181476 A1
(43) Pub. Date: Jun. 23, 2016

(54) MICRO LED WITH DIELECTRIC SIDE MIRROR

(71) Applicant: Apple Inc., Cupertino, CA (US)

(72) Inventors: Kevin K. C. Chang, San Jose, CA (US); Hsin-Hua Hu, Los Altos, CA (US); Clayton Ka Tsun Chan, Fremont, CA (US); Chien-Hsing Huang, Kinmen County (TW)

(21) Appl. No.: 14/803,991

(22) Filed: Jul. 20, 2015

Related U.S. Application Data
(60) Provisional application No. 62/093,078, filed on Dec. 17, 2014.

(51) Int. Cl. H01L 33/38; H01L 33/48; H01L 33/60; H01L 25/075; H01L 33/06; H01L 33/62

(52) U.S. Cl. CPC H01L 33/38; H01L 33/06; H01L 33/62; H01L 33/60; H01L 25/0753; H01L 33/483

(57) ABSTRACT

LEDs and an electronic device are disclosed. In an embodiment an LED includes a p-n diode and a dielectric mirror spanning along a lateral sidewall of the p-n diode and directly underneath the p-n diode. An opening is formed in the dielectric mirror directly underneath the p-n diode, and a bottom conductive contact is on the dielectric mirror directly underneath the p-n diode and within the opening in the dielectric mirror.

### RELATED APPLICATIONS

This application claims the benefit of priority from U.S. Provisional Application No. 62/093,078, filed on Dec. 17, 2014, which is herein incorporated by reference.

### BACKGROUND

1. Field

Embodiments relate to light emitting diodes. More particularly embodiments relate to a light emitting diode with a dielectric mirror.

2. Background Information

Light emitting diodes (LEDs) are increasingly being considered as a replacement technology for existing light sources. For example, LEDs are found in signage, traffic signals, automotive tail lights, mobile electronics displays, and televisions. Various benefits of LEDs compared to traditional lighting sources may include increased efficiency, longer lifespan, variable emission spectra, and the ability to be integrated with various form factors.

One type of LED is an organic light emitting diode (OLED) in which the emissive layer of the diode is formed of an organic compound. One advantage of OLEDs is the ability to print the organic emissive layer on flexible substrates. OLEDs have been integrated into thin, flexible displays and are often used to make the displays for portable electronic devices such as mobile phones and digital cameras. When an OLED display is observed in a bright environment, reflection from the display substrate can result in deterioration of the contrast ratio. For example, ambient light may reflect off of a reflective electrode for the organic emissive layer. Accordingly, a circular polarizer is commonly located between a transparent protective cover plate and the display substrate of an electronic device to alleviate ambient light reflection. A circular polarizer may reduce brightness of the display, for example, by as much as 50%.

### SUMMARY

An LED and electronic device are described. In an embodiment an LED includes a p-n diode and a dielectric mirror spanning along a lateral sidewall of the p-n diode and directly underneath the p-n diode. For example, the dielectric mirror may completely laterally surround the p-n diode, and may completely laterally surround an entire thickness of the p-n diode. The LED may be a vertical LED. An opening is formed in the dielectric mirror directly underneath the p-n diode, and a bottom conductive contact is formed on the dielectric mirror directly underneath the p-n diode and within the opening in the dielectric mirror. In an embodiment the opening formed in the dielectric mirror includes tapered sidewalls. In an embodiment, the bottom conductive contact includes a recessed center area. The bottom conductive contact may include a multiple layer stack.

The dielectric mirror may include pairs of dielectric layers with difference refractive indices. In an embodiment, the dielectric mirror includes a first dielectric layer and second dielectric layer laterally outside of the first dielectric layer, with a refractive index of the first dielectric layer being lower than a refractive index of the second dielectric layer. In an embodiment, a difference between the first refractive index and the second refractive index is at least 0.4. In an embodiment, the first dielectric layer is characterized by a larger band gap, than materials forming the p-n diode. Exemplary materials for the first dielectric layer include, but are not limited to, Al₂O₃, MgF₂, MgO, and CaF₂. Exemplary materials for the second dielectric layer include, but are not limited to, AlN, ZnO, ZnS, ZrO₂, and GaN. The first dielectric layer and the second dielectric layer may have approximately a same thickness. For example, each layer may have a thickness of a quarter of the peak emission wavelength of the p-n diode (λ/4), divided by the refractive index of the dielectric layer (n). The dielectric layer may additionally include multiple pairs of the first and second dielectric layers.

In an embodiment, an electronic device includes a display substrate and a plurality of vertical LEDs bonded to a corresponding plurality of driver contacts in a display region of the display substrate. In an embodiment, a transparent protective cover plate is secured over the display region of the display substrate, and a polarizer film is not located between the transparent protective cover plate and the display substrate. The transparent protective cover plate is exposed to ambient atmosphere.

As described above, the opening formed in the dielectric mirror for each vertical LED may include tapered sidewalls. The bottom conductive contact for each vertical LED may include a multiple layer stack, which may additionally include a bottom-most layer comprising a noble metal. Each vertical LED is bonded to a corresponding driver contact with a solder bond. Each solder bond may additionally be pooled within a recessed center area of a corresponding vertical LED. Each solder bond may additionally be diffused with the bottom-most layer of a corresponding vertical LED. For example, this may form an alloy or intermetallic compound with a melting temperature that is higher than the solder material that is not diffused with the bottom-most layer.

The plurality of vertical LEDs may be further integrated onto the display substrate by forming an insulating layer surrounding each p-n diode, and a top electrode layer spanning over the insulating layer surrounding each p-n diode and spanning over and in electrical contact with each vertical LED. The insulating layer may include a plurality of laterally separate insulating layer portions, each laterally separate portion corresponding to a vertical LED. In an embodiment, each laterally separate insulating layer portion is pooled around a corresponding vertical LED within a corresponding bank structure.

### BRIEF DESCRIPTION OF THE DRAWINGS

FIG. 1 is a cross-sectional side view illustration of a vertical LED.

FIG. 2 is a cross-sectional side view illustration of a vertical LED including a dielectric mirror in accordance with an embodiment.

FIG. 3 is a cross-sectional side view illustration of a vertical LED including a dielectric mirror in accordance with an embodiment.

FIG. 4 is a cross-sectional side view illustration of a bulk LED substrate in accordance with and embodiment.

FIG. 5 is a cross-sectional side view illustration of a p-n diode layer patterned to form an array of mesa structures in accordance with an embodiment.

FIG. 6 is a cross-sectional side view illustration of a dielectric mirror layer deposited over a patterned p-n diode layer in accordance with an embodiment.

FIG. 7 is a cross-sectional side view illustration of an array of bottom conductive contacts formed over an array of openings in a dielectric mirror layer in accordance with an embodiment.

FIG. 8 is a cross-sectional side view illustration of a patterned sacrificial release layer over an array of mesa structures in accordance with an embodiment.

FIG. 9 is a cross-sectional side view illustration of a growth substrate bonded to a carrier substrate with a stabilization layer in accordance with an embodiment.

FIG. 10 is a cross-sectional side view illustration of a carrier substrate after removal of a growth substrate in accordance with an embodiment.

FIG. 11 is a cross-sectional side view illustration of a thinned down p-n diode layer in accordance with an embodiment.

FIG. 12 is a cross-sectional side view illustration of an array of top conductive contacts formed over an array of p-n diodes in accordance with an embodiment.

FIG. 13 is a cross-sectional side view illustration of a sacrificial release layer removed from a carrier substrate including an array of LEDs on stabilization posts in accordance with an embodiment.

FIGS. 14-19 are cross-sectional side view illustrations of a method of transferring an array of LEDs from a carrier substrate to a receiving substrate in accordance with an embodiment.

FIG. 20 is a cross-sectional side view illustration of a insulating layer formed around the array of LEDS and a top electrode layer formed over the array of LEDs in accordance with an embodiment.

FIG. 21 is a cross-sectional side view illustration of a black matrix layer and protective cover plate formed over the array of LEDs in accordance with an embodiment.

FIG. 22 is a schematic illustration of an emissive LED display that does not include a polarizer film between a display substrate and cover plate in accordance with an embodiment.

FIG. 23 is a schematic illustration of a display system in accordance with an embodiment.

### DETAILED DESCRIPTION

Embodiments describe LEDs including integrated dielectric mirrors, and LED integration schemes for electronic devices. In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “spanning”, “to”, “between” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

In one aspect, embodiments describe an LED including an integrated dielectric mirror. The dielectric mirror may span along lateral sidewalls of the p-n diode of the LED and underneath the p-n diode. In such a configuration, light extraction efficiency may be increased. The dielectric mirror may also electrically insulate lateral sidewalls of the LED. In an embodiment, the materials forming the dielectric side mirror have a larger band gap than the materials forming the p-n diode. In this manner, the materials forming the dielectric side mirror are insulative compared to the p-n diode. In such an arrangement, the dielectric side mirror functions as an electrically insulating layer around the lateral sidewalls of the p-n diode, and protects against shorting across the p-n diode, particularly after the formation of a top electrode layer.

In another aspect, embodiments describe a vertical LED including a bottom contact with a recessed center area. The recessed center area may aid in bonding the vertical LED to a driver contact. For example, the recessed center area may form a reservoir volume where a solder bonding material can pool when bonding the vertical LED to a driver contact, and reduce the potential for the reflowed bonding material to creep along the sidewalls of the vertical LED and provide a possible path for electrical shorting.

In another aspect, embodiments describe an electronic device in which a transparent protective cover plate is secured over the display region of the display substrate, and a polarizer film is not located between the transparent protective cover plate and the display substrate. In conventional display devices a polarizer film (e.g. circular polarizer) is commonly located above a display region to provide more uniform brightness or tone of light emitted from the display region. For example, a polarizer film can filter out ambient light that is reflected from reflective surfaces in the display region and improve contrast ratio. In an embodiment, each LED includes an integrated mirror. In this manner, additional reflective surfaces can be removed from the display substrate, or otherwise reduced or covered, alleviating the reflection of ambient light. A dielectric mirror may include one or more pairs of layers with different refractive indices, with a thickness of each layer at approximately a quarter wavelength of the peak light emission wavelength from a corresponding p-n diode (λ/4), divided by the refractive index of the dielectric mirror layer (n). Thus, the dielectric side mirror may be selective to the wavelength of light which is reflected, as well as to the direction of the incoming light waves.

In accordance with embodiments, the LEDs may be “micro” LEDs. As used herein the term “micro” is meant to refer to the scale of 1 to 300 μm. For example, a micro LED may have a maximum lateral (width or length) dimension of 1 to 300 μm. In an embodiment a micro LED may have a maximum lateral (width or length) dimension of 1 to 100 μm, or more specifically 1 to 10 μm.

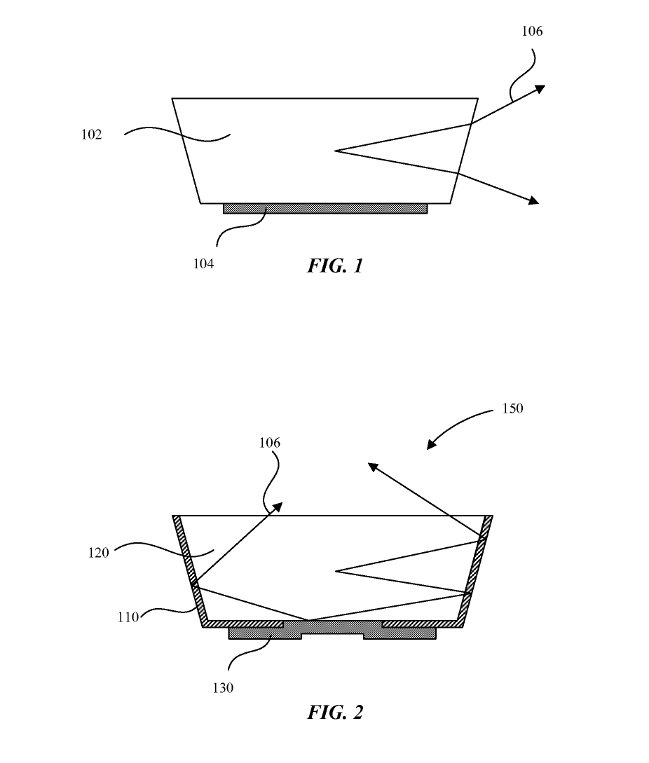

Referring to FIG. 1, a vertical LED is illustrated including a p-n diode 102 and bottom contact 104. Light 106 emitted from the LED may be directed laterally from the LED. If integrated into a display panel, additional mirror structures may be needed in order to reflect the laterally emitted light out of the display. Referring now to FIG. 2, an LED 150 in accordance with an embodiment includes a p-n diode 120, integrated dielectric mirror 110, and bottom contact 130. As illustrated, LED 150 is a vertical LED. Light 106 emitted laterally from the p-n diode 120 may be reflected by the dielectric mirror 110. Once integrated into a display, the reflected light may be within a designed viewing angle such that light extraction efficiency of the display is increased.

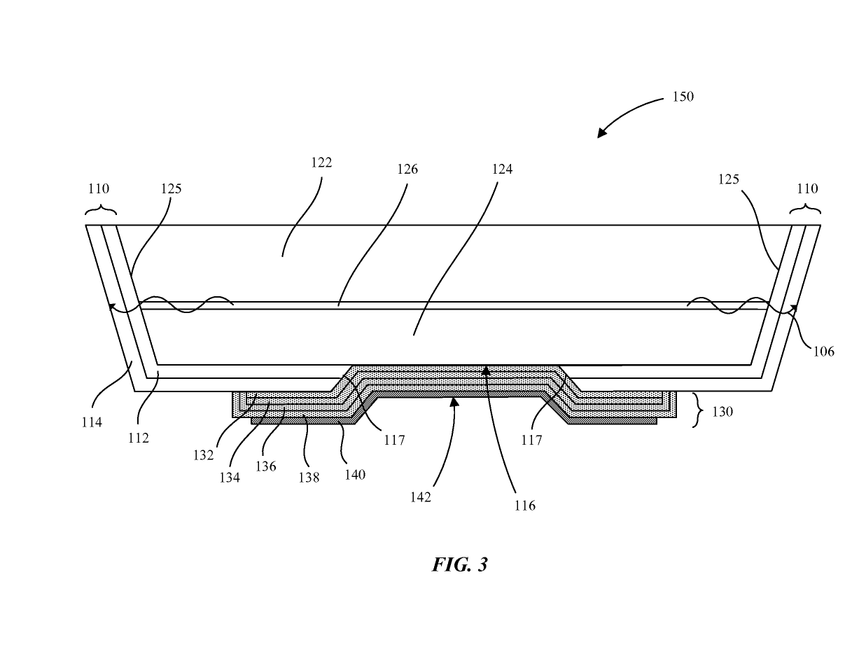

Referring now to FIG. 3, an enlarged view of LED 150 is illustrated in accordance with an embodiment. As illustrated, the p-n diode 120 of the LED 150 includes a p-doped layer 124, an n-doped layer 122, and one or more quantum well layers 126 between the n-doped layer and the p-doped layer. In an embodiment, doping of p-doped layer 124 and n-doped layer 122 is reversed. A dielectric mirror 110 spans along lateral sidewalls 125 of the p-n diode 120. In an embodiment, the dielectric mirror 110 spans along a lateral sidewall 125 of the p-n diode 120 and directly underneath the p-n diode. For example, the dielectric mirror 110 may completely laterally surround the p-n diode 120, and may completely laterally surround an entire thickness of the p-n diode 120.

In the embodiment illustrated, an opening 116 is formed in the dielectric mirror 110 directly underneath the p-n diode 120, and a bottom conductive contact 130 is formed on the dielectric mirror 110 directly underneath the p-n diode and within the opening 116 in the dielectric mirror. In an embodiment, the opening 116 includes tapered sidewalls 117. For example the tapered sidewalls may be at an angle of 30 to 60 degrees, or more particularly 45 degrees to the bottom surface of the p-n diode 120. The tapered sidewalls may be outwardly tapered, such that they are narrower at the p-n diode 120 than at the outermost surface of the dielectric mirror. Tapered sidewalls 117 may aid in achieving adequate step coverage for a deposited bottom conductive contact 130.

As shown, a topography of the bottom conductive contact 130 at least partially conforms to the dielectric mirror and exposed bottom surface of the p-n diode 120. In an embodiment, the bottom conductive contact 130 includes a recessed center area 142. For example, the recessed center area may be defined by the thickness of the bottom conductive contact 130, size of opening 116 and thickness of the bottom conductive contact 130.

The bottom conductive contact 130 may include a multiple layer stack. In an embodiment, bottom conductive contact 130 has a thickness of approximately 0.1 μm-2 μm, and may include a plurality of different layers. For example, bottom conductive contact 130 may include an electrode layer 132 for ohmic contact, an optional mirror layer 134, an adhesion/barrier layer 138, a diffusion barrier layer 138, and a bonding layer 140. In an embodiment, electrode layer 132 may make ohmic contact to the p-doped layer 124. For example, electrode layer 132 may be formed of a high work-function metal such as nickel. In an embodiment, optional mirror layer 134 such as aluminum is formed over the electrode layer 132 to reflect the transmission of the visible wavelength. In an embodiment, titanium is used as an adhesion/barrier layer 136, and platinum is used as a diffusion barrier 138 to bonding layer 140. Bonding layer 140 may be formed of a variety of materials which can be chosen for bonding to the receiving substrate. In an embodiment, bonding layer 140 is formed of a conductive material (both pure metals and alloys) into which a solder material (e.g. indium, bismuth, tin) on a receiving substrate can diffuse. In an embodiment, bonding layer 140 is formed of a noble metal, such as gold or silver.

In an embodiment, dielectric mirror 110 includes one or more pairs of dielectric layers. In the embodiment illustrated a pair includes a first dielectric layer 112 formed on sidewalls 125 and underneath the p-n diode, and a second dielectric layer 114 formed on the first dielectric layer 112. In an embodiment, dielectric mirror 110 includes multiple pairs of the first and second dielectric layers 112, 114. The dielectric layers 112, 114 may be characterized with different refractive indices. For example, refractive index of the first dielectric layer 112 may be lower than the refractive index of the second dielectric layer 114 that is laterally outside of the first dielectric layer 112. In an embodiment, a difference between the refractive indices of the first and second dielectric layers 112, 114 is at least 0.4. In an embodiment, a difference between the refractive indices of the first and second dielectric layers 112, 114 is at least 0.7.

The dielectric layers 112, 114 forming the dielectric mirror 110 may additionally be characterized as possessing suitable etch resistance to an etchant used for removal of a sacrificial release layer, such as a vapor HF etchant. In one aspect, embodiments describe an arrangement of LEDs on a carrier substrate in which the LEDs are poised for pick up and transfer to a receiving substrate. In an embodiment, a sacrificial release layer formed of a suitable material such as SiO₂ is formed around the LEDs, and then selectively removed using a vapor HF etchant. In accordance with embodiments, the dielectric layers 112, 114 forming the dielectric mirror 110 possess suitable resistance to vapor HF etching in order to remove the sacrificial release layer without compromising the integrity of the dielectric mirror.

In an embodiment, the first dielectric is formed of Al₂O₃ (n=1.76), MgF₂ (n=1.38), MgO (n=1.74), or CaF₂ (n=1.43). In an embodiment, the second dielectric layer is formed of AlN (n=2.16), ZnO (n=2), ZnS (n=1.76), ZrO₂ (n=2.22), or GaN (n=2.3). In accordance with embodiments, the first dielectric layer 112 and the second dielectric layer 114 are each characterized by a larger band gap than the materials forming the vertical p-n diode 120. For example, an undoped GaN dielectric mirror layer is characterized by a larger band gap than a doped GaN p-n diode layer. In this manner, the dielectric mirror 110 is more insulating than the p-n diode 120 and electrically passivates the sidewalls 125. In accordance with embodiments, a “dielectric” mirror layer may include materials commonly characterized as dielectrics such as metal oxides, and semiconductor materials, so long as the materials forming the dielectric mirror are more insulating than the p-n diode so that current does not preferentially flow through the mirror instead of the p-n diode. In an embodiment, each of the first and second dielectric layers 112, 114 each have approximately the same thickness. For example, the thickness may be approximately one quarter of the peak emission wavelength of light 106 emitted from the p-n diode 120 (λ/4), divided by the refractive index of the dielectric layer (n). Thus, thickness may be a function of emission wavelength such as red (e.g. 620 nm-750 nm), green (e.g. 495 nm-570 nm), and blue (e.g. 450 nm-495 nm). As already described, the dielectric mirror may include multiple pairs of the dielectric layers 112, 114. While increasing the number of pair of dielectric layers may increase total reflectance of the dielectric mirror, a practical upper limit for the number of pairs, and thickness of the dielectric mirror, may be partly determined by the time required for growth of the dielectric layers, such as by atomic layer deposition (ALD) or spacing allowed between mesa structures 129 (FIG. 5) during formation of the LEDs. In an embodiment, an upper limit for total thickness of the dielectric mirror is approximately 0.5 μm. In an embodiment, an upper limit for total thickness of the dielectric micro is approximately 0.75 μm. In an embodiment, the dielectric mirror includes 3-4 pairs of dielectric layers. Thus, there may be a tradeoff with the amount of reflectance that can be obtained and a practical thickness of the dielectric mirror. Reflectance may additionally be increased by selecting dielectric layers with a larger difference in refractive indices. Exemplary and non-limiting pairs of dielectric layers are provided in Table 1.

TABLE 1
Dielectric mirror layers

| First | Second | Refractive | |
|---|---|---|---|
| dielectric | dielectric | Index | Pair thickness (nm) |
| layer (n) | layer (n) | difference | (@ 625 nm λ) |
| Al₂O₃ | ZrO₂ | 0.46 | 88.78 + 70.38 = 159.16 |
| (1.76) | (n = 2.22) | | |
| Al₂O₃ | GaN | 0.54 | 88.78 + 67.93 = 156.71 |
| (1.76) | (n = 2.3) | | |
| CaF₂ | ZrO₂ | 0.79 | 109.27 + 70.38 = 179.65 |
| (n = 1.43) | (n = 2.22) | | |
| MgF₂ | ZrO₂ | 0.84 | 113.22 + 70.38 = 183.60 |
| (n = 1.38) | (n = 2.22) | | |
| CaF₂ | GaN | 0.87 | 109.27 + 67.93 = 177.20 |
| (n = 1.43) | (n = 2.3) | | |
| MgF₂ | GaN | 0.91 | 113.22 + 67.93 = 181.15 |
| (n = 1.38) | (n = 2.3) | | |

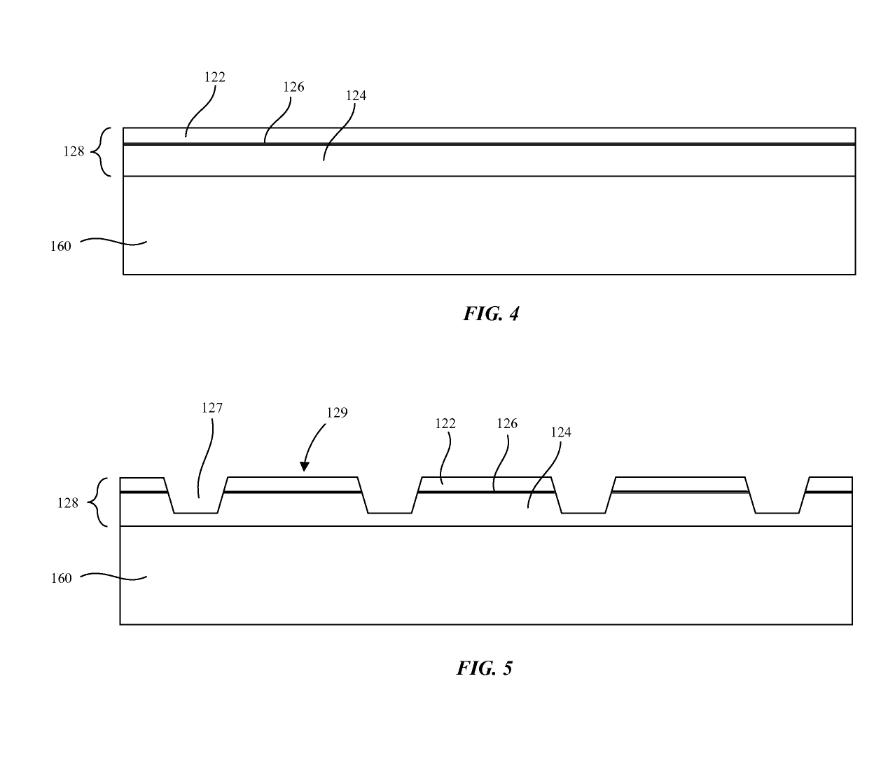

FIG. 4 is a cross-sectional side view illustration of a bulk LED substrate in accordance with an embodiment. In the illustrated embodiment, bulk LED substrate includes a growth substrate 160 and a p-n diode layer 128. The bulk LED substrate illustrated in FIG. 4 may be designed for emission of primary red light (e.g. 620-750 nm wavelength), primary green light (e.g. 495-570 nm wavelength), or primary blue light (e.g. 450-495 nm wavelength), though embodiments are not limited to these exemplary emission spectra. The p-n diode layer 128 may be formed of a variety of compound semiconductors having a band gap corresponding to a specific region in the spectrum. For example, the p-n diode layer 128 can include one or more layers based on II-VI materials (e.g. ZnSe) or III-V materials including III-V nitride materials (e.g. GaN, AlN, InN, InGaN, and their alloys) and III-V phosphide materials (e.g. GaP, AlGaInP, and their alloys). The growth substrate 160 may include any suitable substrate such as, but not limited to, silicon, SiC, GaAs, GaN, and sapphire.

In an embodiment, growth substrate 160 is sapphire and may be approximately 500 μm thick. Using a sapphire growth substrate may correspond with manufacturing blue emitting LEDs (e.g. 450-495 nm wavelength) or green emitting LEDs (e.g. 495-570 nm wavelength). In the illustrated embodiment, p-n diode layer 128 includes one or more quantum well layers 126 between doped semiconductor layer 122 (e.g. n-doped) and doped semiconductor layer 124 (e.g. p-doped), although the doping of layers 122, 124 may be reversed. In an embodiment, doped semiconductor layer 122 is formed of GaN and is approximately 0.1 μm to 3 μm thick. The one or more quantum well layers 126 may have a thickness of approximately 0.5 μm. In an embodiment, doped semiconductor layer 124 is formed of GaN, and is approximately 0.1 μm to 2 μm thick. While the specific embodiments described an illustrated are made with regard to a p-n diode layer 128 including top and bottom doped layers, and a quantum well layer, additional layers may be included including cladding layers, barrier layers, layers for ohmic contact etc., as well as buffer layers for aiding in epitaxial growth and etch stop layers. Accordingly, a three layer p-n diode layer 128 is to be understood as illustrative and not limiting.

It is also to be appreciated, that while the specific embodiments illustrated and described in the following description may be directed to formation of green or blue emitting LEDs, the following sequences and descriptions are also applicable to the formation of LEDs that emit wavelengths other than blue and green. For example, the bulk LED substrate may correspond to red emitting LEDs. For example, growth substrate 160 may be formed of GaAs, and p-n diode layer 128 includes a doped semiconductor layer 122 (e.g. n-doped) formed of AlGaInP and a doped semiconductor layer 124 (e.g. p-doped) formed of GaP.

FIG. 5 is a cross-sectional side view illustration of p-n diode layer 128 patterned to form an array of mesa structures 129 over growth substrate 160 in accordance with an embodiment. Etching of layers 122, 124, 126 of p-n diode layer 128 may be accomplished using suitable etch chemistries for the particular materials. For example, layers 122, 124, 126 may be dry etched in one operation with a BCl₃ and Cl₂ chemistry. As FIG. 5 illustrates, p-n diode layer 128 may not be etched completely through which leaves unremoved portions of p-n diode layer 128 that connect the mesa structures 129. In one example, the etching of p-n diode layer 128 is stopped in n-doped semiconductor layer 124 (or in a buffer layer for epitaxial growth of the p-n diode layer, or on an etch stop layer within the illustrated layer 124). Height of the mesa structures 129 (not including the thickness of the unremoved portions) may correspond substantially to the height of the laterally separate p-n diodes 120 to be formed.

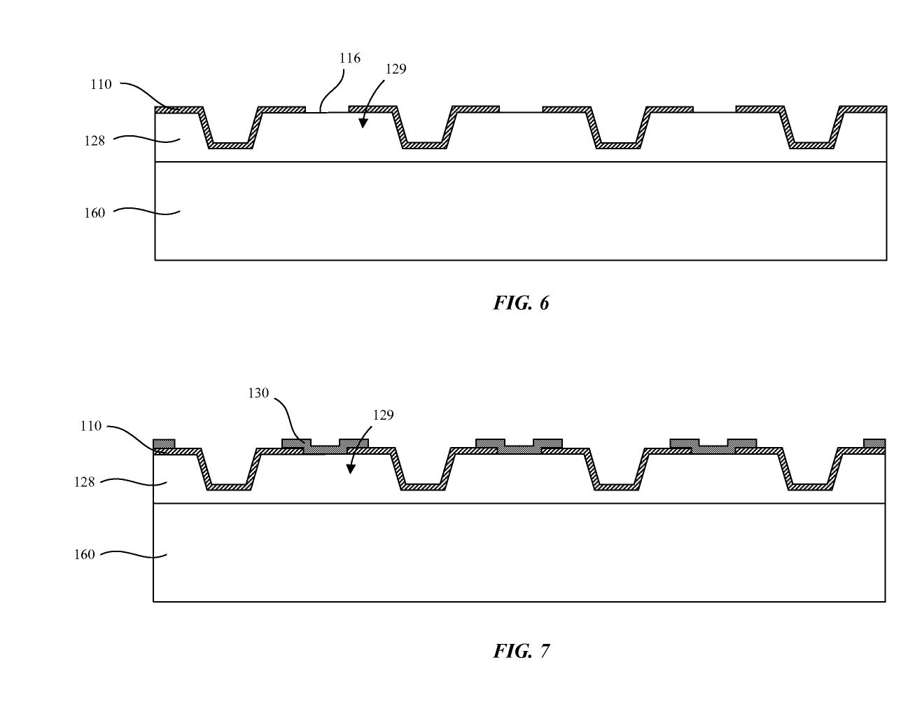

Referring now to FIG. 6, a dielectric mirror layer 110 is deposited over the patterned p-n diode layer and then patterned to form openings 116 over each mesa structure 129. In an embodiment, dielectric mirror layer 110 is formed using ALD in order to precisely control the thickness of each dielectric layer and provide better step coverage than might be accomplished using alternative deposition techniques. For example, ALD may allow for uniform thickness of the dielectric mirror layer on the top and sidewalls of the mesa structures 129. ALD is also useful for controlled uniformity across the wafer. Thus, ALD is useful for obtaining controlled thickness uniformity within the wafer and from wafer to wafer. In an embodiment, dielectric mirror layer 110 is etched using lithography, and dry etching to form openings 116. In an embodiment, openings 116 have tapered sidewalls 117 as described above with regard to FIG. 3. In an embodiment, tapered sidewalls 117 are formed by resist shaping techniques, such as changing the depth of focus of the optics during photoresist exposure, reflowing the photoresist after patterning openings in the photoresist, or isotropic dry etching of the patterned openings in the photoresist. In an embodiment, dry etching is selective to both the photoresist and the dielectric mirror layer 110 to achieve tapered sidewalls 117. Suitable etching chemistries may include BCl₃, Cl₂, Ar, HBr, SiCl₄, and combinations thereof.

Following the formation of dielectric mirror layer 110, an array of bottom conductive contacts 130 are formed over the array of openings 116 and on the dielectric mirror layer 110 as illustrated in FIG. 7 using suitable techniques such as sputtering or electron beam physical deposition followed by etching or liftoff. Following the formation of the bottom conductive contacts 130, the substrate stack can be annealed to form an ohmic contact. For example, a p-side ohmic contact may be formed by annealing the substrate stack at 510° C. for 10 minutes. In an embodiment where bonding layer 140 has a liquidus temperature below the annealing temperature, the bonding layer 140 may be formed after annealing.

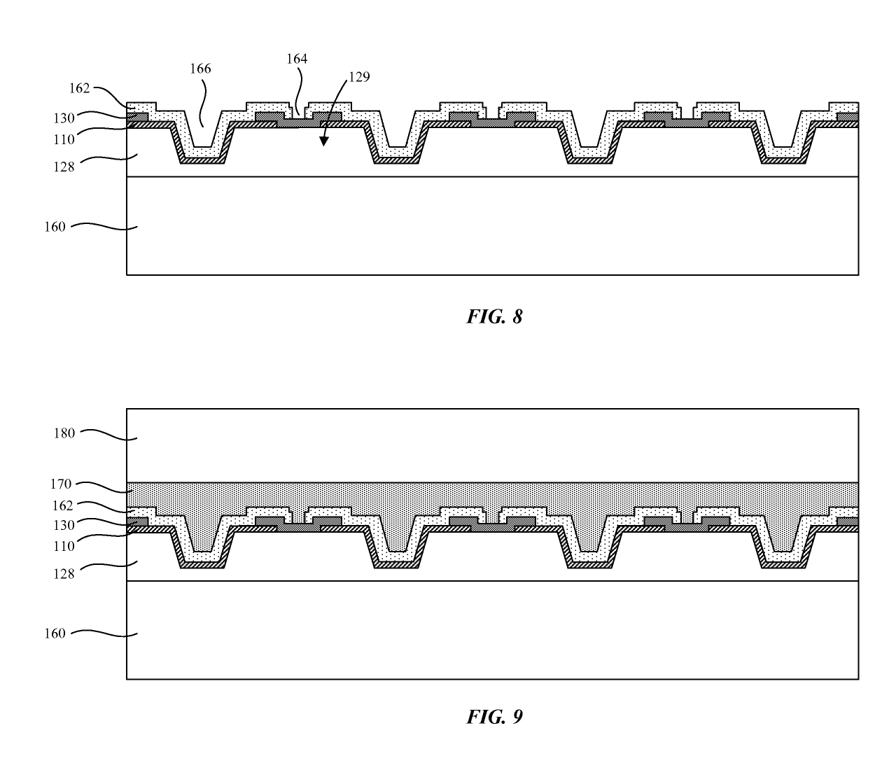

FIG. 8 is a cross-sectional side view illustration of a sacrificial release layer 162 including an array of openings 164 formed over the array of mesa structures 129 in accordance with an embodiment. In an embodiment, sacrificial release layer 162 is between approximately 0.5 and 2 microns thick. In an embodiment, sacrificial release layer 162 is formed of an oxide (e.g. SiO₂) or nitride (e.g. SiNₓ), though other materials may be used which can be selectively removed with respect to the other layers, including the dielectric mirror layer 110. In an embodiment, sacrificial release layer 162 is deposited by sputtering, low temperature plasma enhanced chemical vapor deposition (PECVD), or electron beam evaporation to create a low quality layer, which may be more easily removed than a higher quality layer deposited by other methods such as atomic layer deposition (ALD) or high temperature PECVD. After forming sacrificial release layer 162, the sacrificial release layer 162 is patterned to form an array of openings 164 over the array of conductive contacts 130. In an example embodiment, a fluorinated chemistry (e.g. HF vapor, or CF₄ or SF₆ plasma) is used to etch the SiO₂ or SiNₓ sacrificial release layer 162.

As will become more apparent in the following description the height, and length and width of the openings 164 in the sacrificial layer 162 correspond to the height, and length and width (area) of the stabilization posts to be formed, and resultantly the adhesion strength that must be overcome to pick up the array of LEDs that are poised for pick up on the array of stabilization posts. In an embodiment, openings 164 are formed using lithographic techniques and have a length and width of approximately 1 μm by 1 μm, though the openings may be larger or smaller so long as the openings have a width (or area) that is less than the width (or area) of the conductive contacts 130 and/or micro LEDs. Furthermore, the height, length and width of the openings 166 between the sacrificial release layer 162 formed along sidewalls between the mesa structures 129 will correspond to the height, length and width of the stabilization cavity sidewalls to be formed. Accordingly, increasing the thickness of the sacrificial release layer 162 and or decreasing the space separating adjacent mesa structures 129 may have the effect of decreasing the size of the stabilization cavity sidewalls.

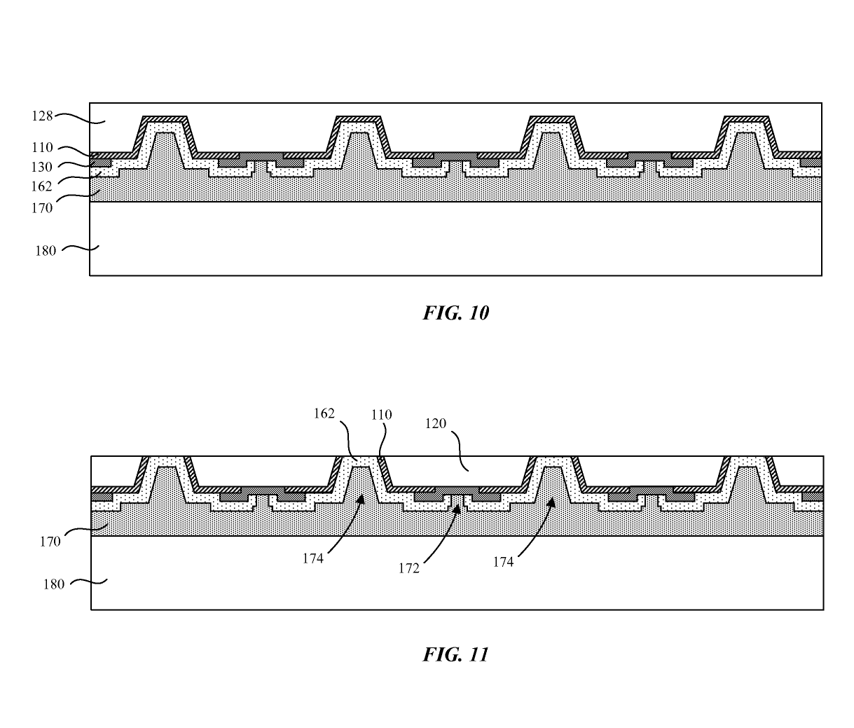

Referring to FIG. 9, in an embodiment a stabilization layer 170 is formed over the sacrificial release layer 162 that is over the array of mesa structures 129 and laterally between the array of mesa structures 129. The portion of the stabilization layer 170 within openings 164 becomes the stabilization posts 172, and the portion of the stabilization layer 170 within the openings 166 becomes the stabilization structure sidewalls 174. In an embodiment, the stabilization layer 170 is formed of a thermoset material such as benzocyclobutene (BCB). Bonding of the carrier substrate 180 to the growth substrate 160 may include curing of the thermoset material. In an embodiment the stabilization layer 170 may be formed from a spin-on electrical insulator material. In such an embodiment, planarization and bonding can be accomplished in the same operation without requiring additional processing such as grinding or polishing.

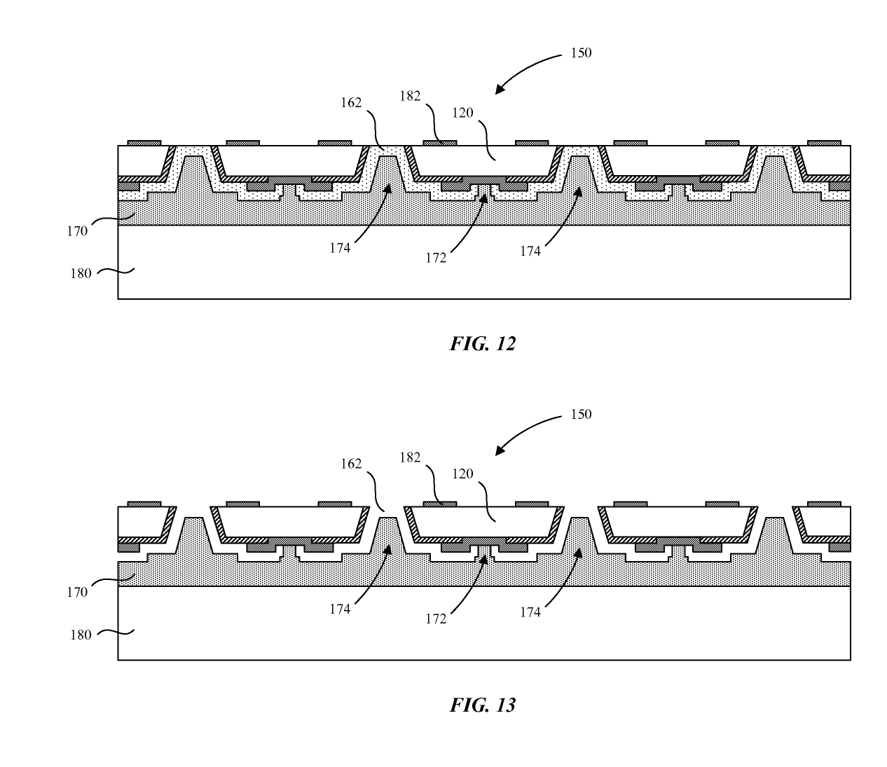

FIG. 10 is a cross-sectional side view illustration of the removal of growth substrate 160 in accordance with an embodiment. When growth substrate 160 is sapphire, laser lift off (LLO) may be used to remove the sapphire. Removal may be accomplished by other techniques such as grinding and etching, depending upon the material selection of the growth substrate 160. Following the removal of the growth substrate 160, the p-n diode layer 128 may be thinned (e.g. n-doped layer 122) to expose the sacrificial release layer 162 as illustrated in FIG. 11. Thinning may be accomplished using one or more of chemical-mechanical-polishing (CMP), dry polishing, or dry etch. FIG. 11 illustrates that the portions of the p-n diode layer 128 that previously connected the mesa structures 129 are now removed, which leaves laterally separated p-n diodes 120. In an embodiment, an exposed top surface of each of the laterally separate p-n diodes 120 is co-planar with an exposed top surface of the dielectric mirror 110 and sacrificial release layer 162.

Referring now to FIG. 12, an array of top conductive contacts 182 may optionally be formed over the array of p-n diodes 120. Conductive contacts 182 may be formed using a suitable technique such as electron beam physical deposition. In an embodiment, conductive contacts 182 include a thin metal layer or layer stack. Conductive contacts 182 may also be a conductive oxide such as indium-tin-oxide (ITO), or a combination of one or more metal layers and a conductive oxide. In an embodiment, the conductive contacts 182 are annealed to generate an ohmic contact with the array of p-n diodes 120. Where conductive contacts are metal, the thickness may be thin for transparency and reflectivity reasons. In an embodiment where conductive contacts are formed of a transparent material such as ITO, the conductive contacts may be thicker, such as 1,000 to 2,000 angstroms.

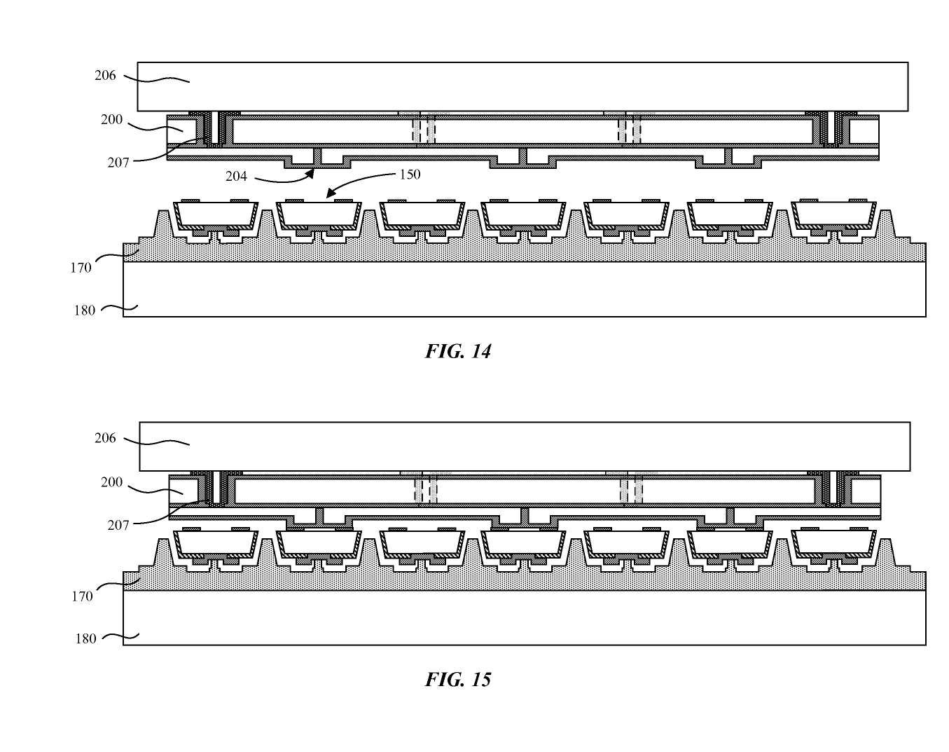

FIG. 13 is a cross-sectional side view illustration of an array of LEDs 150 formed on array of stabilization posts 172 after removal of sacrificial release layer 162 in accordance with an embodiment. In the embodiments illustrated, sacrificial layer 162 is removed resulting in an open space between each LED and the stabilization layer 170. As illustrated, there is an open space below each LED 150 as well as open space between each LED 150 and stabilization cavity sidewalls 174 of stabilization layer 170. A suitable etching chemistry such as HF vapor, CF₄, or SF₆ plasma may be used to etch the SiO₂ or SiNₓ of sacrificial release layer 162. In an embodiment the etching chemistry is HF vapor, and the sacrificial release layer 162 is selectively removed relative to the LEDs 150 and stabilization layer 170, without substantial degradation of the dielectric mirror 110.

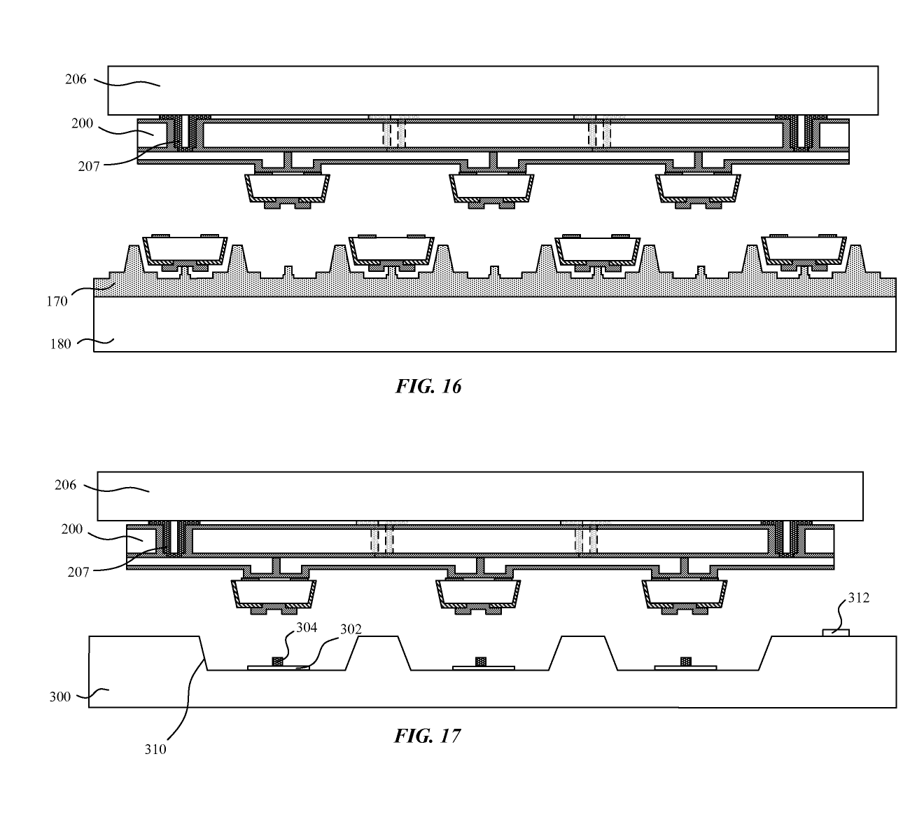

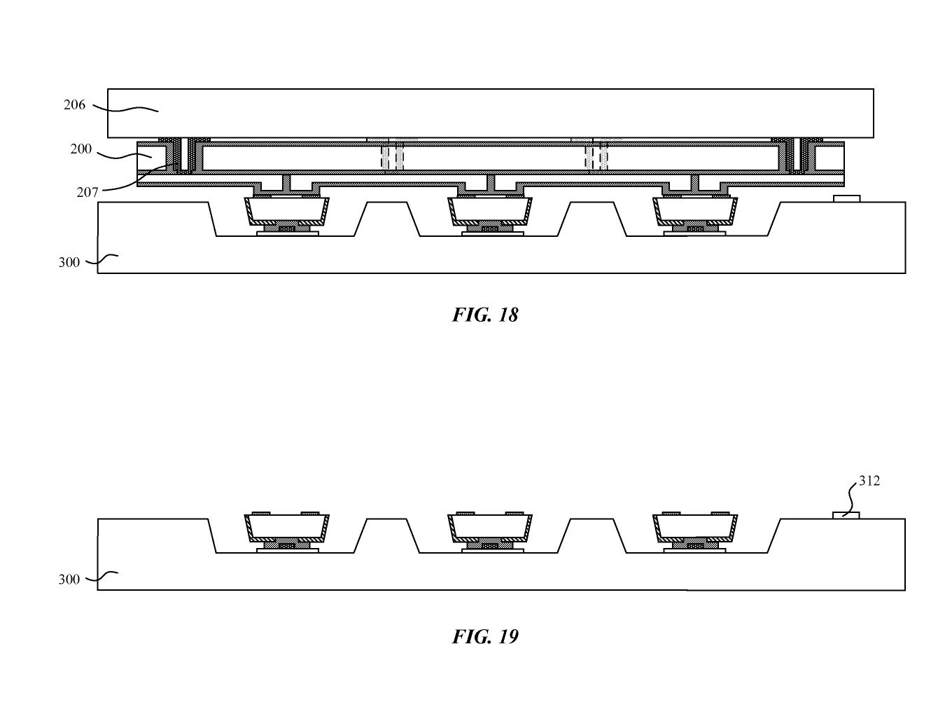

After sacrificial release layer 162 is removed, the array of LEDs 150 supported only by the array of stabilization posts 172 is poised for pick up and transfer to a receiving substrate. FIGS. 14-19 are cross-sectional side view illustrations for a method of transferring an array of micro LEDs from a carrier substrate to a receiving substrate in accordance with embodiments. FIG. 14 is a cross-sectional side view illustration of an array of transfer heads 204 supported by substrate 200 and positioned over an array of micro LEDs 150 in accordance with an embodiment. The array of micro LEDs 150 are then contacted with the array of transfer heads 204 as illustrated in FIG. 15. As illustrated, the pitch of the array of transfer heads 204 is an integer multiple of the pitch of the array of micro LEDs 150. A voltage is applied to the array of transfer heads 204. The voltage may be applied from the working circuitry within a transfer head assembly 206 in electrical connection with the array of transfer heads through vias 207. The array of micro LEDs 150 is then picked up with the array of transfer heads 204 as illustrated in FIG. 16. The array of micro LEDs 150 is then positioned over a receiving substrate 300 as illustrated in FIG. 17. In an embodiment the receiving substrate 300 is a display substrate. For example, the receiving substrate 300 may include an array of driver contacts 302, and optionally an array of bank structures 310 within subpixel areas. A solder material pillar 304 may be formed on each driver contact 302 for bonding with an LED 150. Referring now to FIG. 18, the array of LEDs 150 are brought into contact with contact pads on receiving substrate 300. Specifically, the recessed center areas 142 of the bottom conductive contacts 130 are brought into contact with the solder material pillars 304. In one embodiment, an operation is performed to diffuse the solder material pillars 304 into the bonding layer 140 of each bottom conductive contact 130 while contacting the array of LEDs with the contact pads 302. For example, an indium, bismuth, or tin solder material pillar 304 may be diffused with a silver or gold bonding layer 140, though other materials may be used. For example, heat can be applied from a heat source located within the transfer head assembly 206 and/or receiving substrate 300. Where solder material pillars 304 are formed of a lower melting temperature material than the bonding layer 140, the solder material pillars 304 may reflow. In an embodiment, the recessed center areas 142 of the bottom conductive contacts 130 create a reservoir volume that retains the reflowed solder material, and restricts the reflowed solder material from creeping out from underneath the LEDs 150. The heating operation may result in the formation of an alloy material, or intermetallic compound with a melting temperature higher than the heating temperature. In an embodiment, sufficient diffusion to adhere the array of LEDs 150 with the array of contact pads 302 can be achieved at temperatures of less than 200° C.

The array of LEDs 150 is then released onto receiving substrate 300 as illustrated in FIG. 19. Releasing the array of LEDs from the transfer heads 204 may be further accomplished with a variety of methods including turning off the voltage sources, lowering the voltage across the pair of transfer head electrodes, changing a waveform of the AC voltage, and grounding the voltage sources.

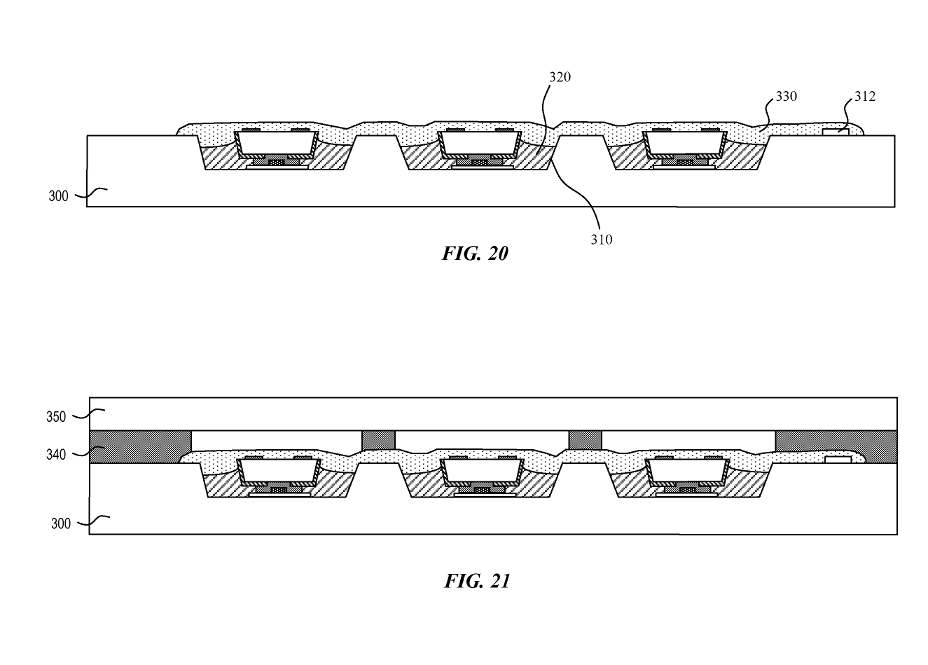

Referring now to FIG. 20, after transferring the array of LEDs to the receiving substrate 300, the LEDs 150 may be further secured within the bank structures 310 with a insulating layer 320. The insulating layer 320 may function to secure the LEDs 150 on the receiving substrate 300. The insulating layer 320 may function to provide step coverage for a top electrode layer 330. In such a configuration, the insulating layer 320 aids in forming a continuous top electrode layer 330, providing step coverage at the sidewalls of the LEDs 150. In the embodiment illustrated, a plurality of laterally separate portions of the insulating layer 320 pool around the LEDs within the bank structures 310. In an embodiment, one or more top electrode layers 330 may be used to provide an electrical connection from the top of each vertical LED 150 to a Vss or ground line 312. For example, the top electrode layer 330 may be formed on the p-n diode 120 or top conductive contact 182 for a vertical LED 150.

Still referring to FIG. 18, the insulating layer 320 may prevent electrical shorting between the top electrode layer 330 and the driver contacts 302. The insulating layer 320 may also cover any portions of the driver contacts 302 in order to prevent possible shorting. The insulating layer 320 may be transparent or semi-transparent to the visible wavelength, or opaque. Insulating layer may be formed of a variety of materials such as, but not limited to epoxy, acrylic (polyacrylate) such as poly(methyl methacrylate) (PMMA), benzocyclobutene (BCB), polyimide, and polyester. In an embodiment, insulating layer 320 is formed by ink jet printing or screen printing around the LEDs 150.

In an embodiment, the top electrode layer or layers 330 are transparent, or semi-transparent to the visible wavelength. For example, in top emission systems the top electrode layer 330 may be transparent, and for bottom emission systems the top electrode layer may be reflective. Exemplary transparent conductive materials include amorphous silicon, transparent conductive oxides (TCO) such as indium-tin-oxide (ITO) and indium-zinc-oxide (IZO), carbon nanotube film, or a transparent conductive polymer such as poly(3,4-ethylenedioxythiophene) (PEDOT), polyaniline, polyacetylene, polypyrrole, and polythiophene. In an embodiment, the top electrode layer 330 includes nanoparticles such as silver, gold, aluminum, molybdenum, titanium, tungsten, ITO, and IZO. In a particular embodiment, the top electrode layer 330 is formed by ink jet printing or screen printing ITO or a transparent conductive polymer such as PEDOT. Other methods of formation may include chemical vapor deposition (CVD), physical vapor deposition (PVD), spin coating.

FIG. 21 is a cross-sectional side view illustration of an embodiment in which a black matrix layer 340 is formed around an LED prior to formation of the protective cover plate 350 in order to block light emission, and to separate light emission from adjacent LEDs 150. In such an embodiment, the structure illustrated in FIG. 21 can emit light through the protective cover plate 350. Black matrix 340 can be formed from a method that is appropriate based upon the material used. For example, black matrix 340 can be applied using ink jet printing, sputter and etching, spin coating with lift-off, or a printing method. Exemplary black matrix materials include carbon, metal films (e.g. nickel, aluminum, molybdenum, and alloys thereof), metal oxide films (e.g. chromium oxide), and metal nitride films (e.g. chromium nitride), organic resins, glass pastes, and resins or pastes including a black pigment or silver particles. In an embodiment, insulating layer 320 is formed of a black matrix material. For example, a black pigment or particles can be included in the previously described insulating layer 320 materials. In an embodiment, a separate black matrix layer 340 may not be applied where insulating layer 320 is formed of a black matrix material.

While the protective cover plate 350 is illustrated as a rigid layer, the protective cover plate 350 may also be conformal to the underlying structure. As illustrated, rigid protective cover plate 350, for example, can be attached to the underlying structure with an adhesive such as a frit glass seal or epoxy formed along the edge of the cover with a dispenser or screen printing. In an embodiment, protective cover plate 350 is transparent glass or plastic. The protective cover plate 350 may be exposed to ambient atmosphere.

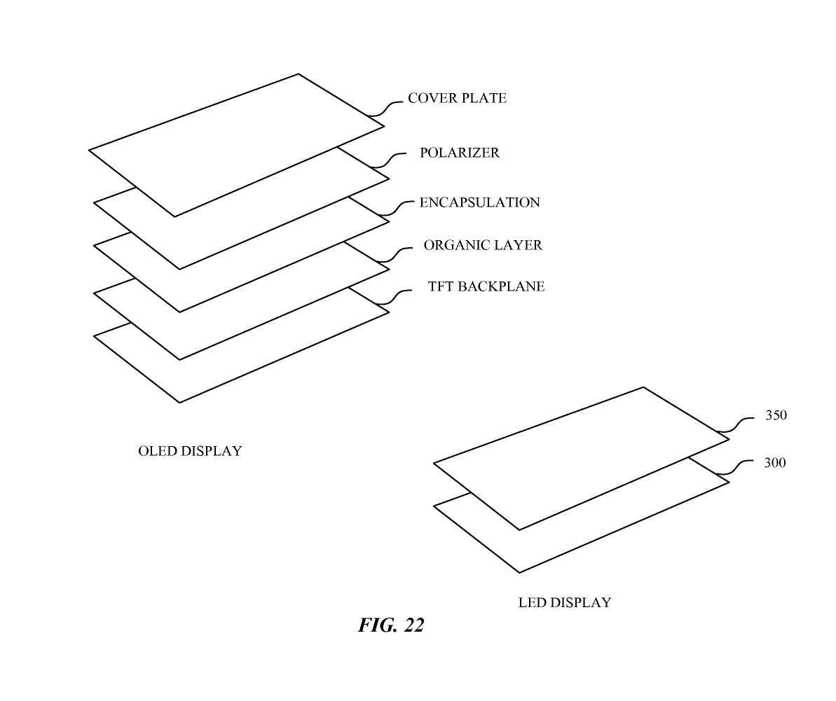

In accordance with embodiments an emissive LED structure is described which incorporates a dielectric mirror within the LED. Further minimization of reflective layers around the LEDs may potentially eliminate the need for the location of a polarizer above the emissive LEDs and below the protective cover plate. For example, a conventional OLED display configuration is illustrated in FIG. 22 alongside an emissive LED display in accordance with an embodiment. As shown a conventional OLED display includes a thin film transistor (TFT) backplane substrate over which organic layers are formed. An encapsulation layer is formed over the organic layers, and a polarizer film is located above the encapsulation layer and below the protective cover plate. The polarizer film may significantly reduce brightness of the OLED display. An LED display stack in accordance with an embodiment does not include a polarizer film between the protective cover plate 350 and the display substrate 300.

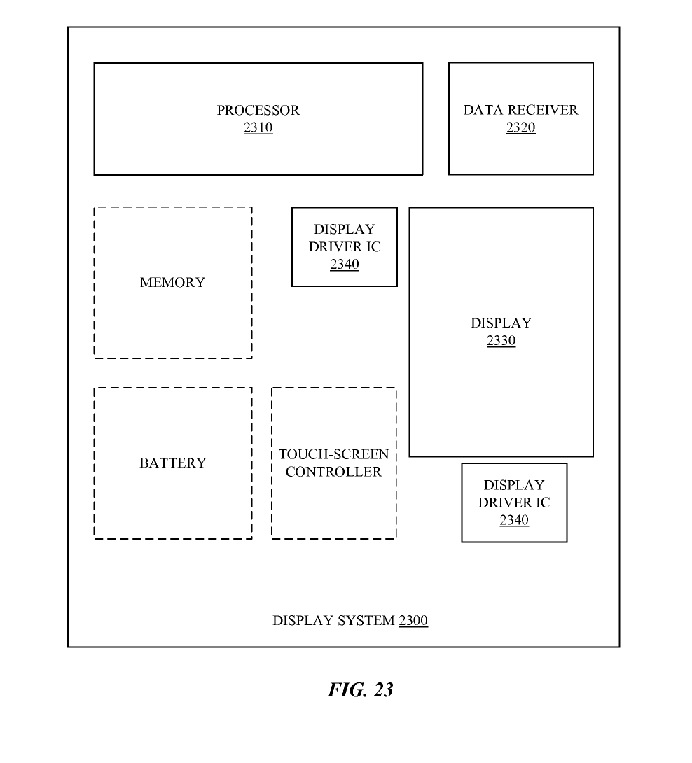

FIG. 23 illustrates a display system 2300 in accordance with an embodiment. The display system houses a processor 2310, data receiver 2320, a display 2330, and one or more display driver ICs 2340, which may be scan driver ICs and data driver ICs. The data receiver 2320 may be configured to receive data wirelessly or wired. Wireless may be implemented in any of a number of wireless standards or protocols. The one or more display driver ICs 2340 may be physically and electrically coupled to the display 2330.

In some embodiments, the display 2130 includes one or more LEDs 150 that are formed in accordance with embodiments described above. Depending on its applications, the display system 2300 may include other components. These other components include, but are not limited to, memory, a touch-screen controller, and a battery. In various implementations, the display system 2300 may be a television, tablet, phone, laptop, computer monitor, kiosk, digital camera, handheld game console, media display, ebook display, or large area signage display.

In utilizing the various aspects of the embodiments, it would become apparent to one skilled in the art that combinations or variations of the above embodiments are possible for forming and integrating a micro LED with a dielectric mirror onto a display or lighting backplane. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An LED comprising:
a p-n diode including:
a p-doped layer;
an n-doped layer; and
a quantum well layer between the n-doped layer and the p-doped layer;
a dielectric mirror spanning along a lateral sidewall of the p-n diode and directly underneath the p-n diode;
an opening in the dielectric mirror directly underneath the p-n diode; and
a bottom conductive contact on the dielectric mirror directly underneath the p-n diode and within the opening in the dielectric mirror.

2. The LED of claim 1, wherein the bottom conductive contact comprises a recessed center area.

3. The LED of claim 2, wherein the opening in the dielectric mirror directly underneath the p-n diode includes tapered sidewalls.

4. The LED of claim 2, wherein the dielectric mirror comprises a pair of dielectric layers including a first dielectric layer with a first refractive index, and a second dielectric layer with a second refractive index.

5. The LED of claim 4, wherein the first refractive index is lower than the second refractive index, and the second dielectric layer is laterally outside of the first dielectric layer.

6. The LED of claim 5, wherein the dielectric mirror comprises multiple pairs of the first and second dielectric layers.

7. The LED of claim 5, wherein a difference between the first refractive index and the second refractive index is at least 0.4.

8. The LED of claim 5, wherein the first dielectric layer and the second dielectric layer have approximately a same thickness.

9. The LED of claim 5, wherein:
the first dielectric layer comprises a material selected from the group consisting of Al₂O₃, MgF₂, MgO, and CaF₂; and
the second dielectric layer comprises a material selected from the group consisting of AlN, ZnO, ZnS, ZrO₂, and GaN.

10. The LED of claim 5, wherein the first dielectric layer is characterized by a larger band gap, than materials forming the p-n diode.

11. An electronic device comprising:
a display substrate;
a plurality of vertical LEDs bonded to a corresponding plurality of driver contacts in a display region of the display substrate;
wherein each vertical LED comprises:
a p-n diode including:
a p-doped layer;
an n-doped layer; and
a quantum well layer between the n-doped layer and the p-doped layer;
a dielectric mirror spanning along a lateral sidewall of the p-n diode and directly underneath the p-n diode;
an opening in the dielectric mirror directly underneath the p-n diode; and
a bottom conductive contact on the dielectric mirror directly underneath the p-n diode and within the opening in the dielectric mirror.

12. The electronic device of claim 11, wherein each opening includes tapered sidewalls.

13. The electronic device of claim 12, wherein each bottom conductive contact comprises a recessed center area.

14. The electronic device of claim 13, wherein each bottom conductive contact comprises a multiple layer stack including a bottom-most layer comprising a noble metal.

15. The electronic device of claim 14, further comprising a plurality of solder bonds connecting the plurality of vertical LEDs to the corresponding plurality of driver contacts.

16. The electronic device of claim 15, wherein each solder bond is pooled within a recessed center area of a corresponding vertical LED.

17. The electronic device of claim 16, wherein each solder bond is diffused with the bottom-most layer of a corresponding vertical LED.

18. The electronic device of claim 16, further comprising an insulating layer surrounding each p-n diode; and
a top electrode layer spanning over the insulating layer surrounding each p-n diode, the top electrode layer spanning over and in electrical contact with each vertical LED.

19. The electronic device of claim 18, wherein the insulating layer comprises a plurality of laterally separate portions of the insulating layer, each laterally separate portion corresponding a vertical LED.

20. The electronic device of claim 11, further comprising a transparent protective cover plate secured over the display region of the display substrate, wherein a polarizer film is not located between the transparent protective cover plate and the display substrate, and the transparent protective cover plate is exposed to ambient atmosphere.
